(19) United States
(12) Patent Application Publication
(10) Pub. No.: US 2013/0087194 A1
(43) Pub. Date: Apr. 11, 2013

(54) SILICON MULTILAYER ANTI-REFLECTIVE FILM WITH GRADUALLY VARYING REFRACTIVE INDEX AND MANUFACTURING METHOD THEREFOR, AND SOLAR CELL HAVING SAME AND MANUFACTURING METHOD THEREFOR

(71) Applicants: Sung Jun Jang, Buk-gu (KR); Yong Tak Lee, Buk-gu (KR); Young Min Song, Buk-gu (KR)

(72) Inventors: Sung Jun Jang, Buk-gu (KR); Yong Tak Lee, Buk-gu (KR); Young Min Song, Buk-gu (KR)

(73) Assignee: GWANGJU INSTITUTE OF SCIENCE AND TECHNOLOGY, Buk-gu, Gwangju (KR)

(21) Appl. No.: 13/703,702

(22) PCT Filed: Jul. 29, 2011
(86) PCT No.: PCT/KR2011/005626

§ 371 Date: Dec. 12, 2012

(30) Foreign Application Priority Data
Aug. 2, 2010 (KR) 10-2010-0074566

(51) Int. Cl. G02B 1/11; H01L 31/028; H01L 31/18; H01L 31/032; H01L 31/0272; H01L 31/0296; H01L 31/0216; H01L 31/0368

(52) U.S. Cl. CPC G02B 1/11; H01L 31/0216; H01L 31/0284; H01L 31/03685; H01L 31/0322; H01L 31/0272; H01L 31/0296; H01L 31/18
USPC 136/258; 427/162; 136/252; 136/261; 136/262; 136/265; 136/260; 359/601; 438/72

(57) ABSTRACT

The present invention relates to a silicon multilayer anti-reflective film with a gradually varying refractive index and a manufacturing method therefor, and a solar cell having the same and a manufacturing method therefor, wherein: the refractive index of a silicon thin film is adjusted by depositing silicon on a semiconductor or glass substrate with a slight tilt; and an anti-reflective film with a gradually varying refractive index is implemented using a silicon multi-layer film in which multi-layer film are stacked with different tilt angles. In addition, the silicon multilayer anti-reflective film according to the present invention is applied to a silicon solar cell, thereby suppressing reflection in the inside of the solar cell and providing an excellent heat radiation characteristic using a high heat transfer coefficient.

### TECHNICAL FIELD

The present invention relates to an anti-reflection film, which can be applied to various optical devices such as optical filters and the like, and optical semiconductor devices such as semiconductor light emitting devices, solar cells and the like, and a manufacturing method thereof. More particularly, the present invention relates to a silicon multilayer anti-reflection film, an index of refraction of which is gradually varied from an index of refraction of an optical device and an optical device material to an index of refraction of air while decreasing the index of refraction of silicon to a very low level through inclined deposition, a solar cell including the same, and manufacturing methods thereof.

### BACKGROUND ART

In accordance with Fresnel's law, the amount of light reflected from a surface between materials having different indexes of refraction increases with increasing difference in index of reflection between the materials. In an optical semiconductor device including a semiconductor material having a high index of refraction, reflection of light at an interface with air due to difference in index of refraction between the device and air is directly related to performance of the device. Thus, minimization of light reflection is an essential problem that has to be solved to provide good device performance, and technologies for minimizing light reflection between an optical device and air with a simple manufacturing method, short processing time, and low costs have been developed.

For example, surface texturing and anti-reflection film coating are generally employed as an anti-reflection method for enhancing efficiency and performance through reduction of light reflection in an optical semiconductor device, such as solar cells, photodetectors, light emitting diodes, etc.

Surface texturing reduces reflection of light on a semiconductor surface by forming regular or irregular structures or curves thereon through a physical or chemical method.

The physical method for surface texturing includes plasma etching, mechanical scribing, etc. These methods have merits in that they can suppress formation of an anisotropic structure and easily adjust the shape and size of the structure due to uniform etching speed regardless of the crystal orientation of the semiconductor substrate. However, these methods are not commercially viable due to disadvantages in that not only is mass production difficult due to a complicated process and long processing time but also expensive vacuum equipment and additional equipment are needed.

Also, the chemical method for surface texturing includes photolithography, wet etching, etc. These methods are not widely used due to disadvantages, such as susceptibility to wavelengths of a light source, difficulty in adjusting a surface shape and etching speed depending on the crystal orientation, the kind of composition elements, composition and doping conditions of the semiconductor substrate, and difficulty in formation of a sufficiently fine structure.

Recently, various studies have been made to provide a nano structure (subwavelength structure, SWS), which has a frequency shorter than or equal to wavelengths of light to provide very low reflectivity in a wide wavelength band and low reflectivity in a wide incident angle range, as compared with the surface texturing.

In existing methods for manufacturing a nanostructure having a frequency shorter than or equal to the wavelength of light, a periodic or aperiodic pattern shorter than or equal to the wavelength of light is formed on a substrate through electron beam lithography, hologram lithography, or nano-imprinting, etc., and used for physical or chemical etching. However, the existing methods are economically infeasible due to expensive equipment, complicated operation, low productivity, long process time, and the like.

Meanwhile, anti-reflection film coating decreases rapid change in index of refraction between the semiconductor material and air by depositing a material having a lower index of refraction than that of the semiconductor material on the semiconductor, thereby reducing reflection of light.

The anti-reflection film coating has advantages of providing minimum reflectivity in a certain wavelength band by adjusting the index of refraction and optical thickness of a coating material, but needs a multilayered structure of two or more materials since it is difficult for a single layer to obtain low reflectivity over a wide area. Also, for an anti-reflection film in which a mixture of two materials is deposited such that the index of refraction can be continuously varied, it is very difficult to adjust the mixing ratio of the materials upon deposition.

In order to solve the problems of the anti-reflection film coating, there has recently been proposed a structure in which the index of refraction is gradually changed through adjustment of an angle of the substrate in a deposition apparatus. As the tilting angle increases, porosity of the film increases and an effective index of refraction of the film decreases due to a shadow effect.

However, this method has disadvantages in that it is difficult to change the index of refraction over a wide range due to the use of oxides and fluorides such as SiO₂, TiO₂, Al₂O₃, MgF₂, the film does not have a dense structure if the tilting angle becomes larger, and heat dissipation of the optical semiconductor device is deteriorated since the oxides and fluorides have low coefficients of heat transfer.

### DISCLOSURE

### Technical Problem

The present invention is conceived to solve such problems in the art, and an aspect of the present invention is to provide an anti-reflection film, which has a gradually vary index of refraction through inclined deposition of a semiconductor material such as silicon, has a dense structure, and shows excellent heat dissipation efficiency due to a higher heat transfer coefficient than existing anti-reflection films, a solar cell including the same, and manufacturing methods thereof.

### Technical Solution

A first aspect of the present invention provides a silicon multilayer anti-reflection film including at least two silicon layers sequentially stacked on a substrate, wherein each silicon layer is obliquely deposited on the substrate by adjusting a tilting angle of the substrate to gradually vary an index of refraction.

The substrate may include a glass substrate or a semiconductor substrate, and the semiconductor substrate may include one of Si, GaAs, InP, GaP, and GaN.

Each of the silicon layers may have a distribution of a gradually increasing or decreasing index of refraction.

The tilting angle may range from 1 to 90 degrees.

The gradually varying index of refraction may be realized through a stepped configuration, and the distribution of the gradually varying index of refraction may include one of linear, polynomial, Gaussian and nonlinear distributions.

A second aspect of the present invention provides a method of manufacturing a silicon multilayer anti-reflection film, which includes sequentially stacking at least two silicon layers on a substrate, wherein each of the silicon layers is obliquely deposited on the substrate by adjusting a tilting angle of the substrate to have a gradually varying index of refraction.

The silicon layer may be obliquely deposited by sputtering or evaporation.

Each of the silicon layers may be obliquely deposited to have a distribution of a gradually increasing or decreasing index of refraction.

The tilting angle may range from 1 to 90 degrees.

The gradually varying index of refraction may be realized through a stepped configuration, and the distribution of the gradually varying index of refraction may include one of linear, polynomial, Gaussian and nonlinear distributions.

A third aspect of the present invention provides a solar cell including a silicon multilayer anti-reflection film, which includes: a first transparent electrode formed on a substrate; a silicon multilayer anti-reflection film obliquely formed on the first transparent electrode to have a gradually varying index of refraction; p-type, i-type and n-type silicon layers sequentially stacked on the silicon multilayer anti-reflection film; a second transparent electrode formed on the n-type silicon layer; and an n-type electrode formed on the second transparent electrode.

The substrate may include a glass substrate or a semiconductor substrate, and the semiconductor substrate may include one of Si, GaAs, InP, GaP, and GaN.

The multilayered structure may include two to five layers.

The silicon multilayer anti-reflection film has a distribution of a gradually increasing or decreasing index of refraction.

The gradually varying index of refraction may be realized through a stepped configuration, and the distribution of the gradually varying index of refraction may include one of linear, polynomial, Gaussian and nonlinear distributions.

A fourth aspect of the present invention provides a method of manufacturing a solar cell including a silicon multilayer anti-reflection film, which includes: forming a first transparent electrode on a substrate; obliquely forming a silicon multilayer anti-reflection film on the first transparent electrode to have a gradually varying index of refraction; sequentially stacking p-type, i-type and n-type silicon layers on the silicon multilayer anti-reflection film; forming a second transparent electrode on the n-type silicon layer; and forming an n-type electrode on the second transparent electrode.

The silicon multilayer anti-reflection film may be formed to have a distribution of a gradually increasing or decreasing index of refraction.

The gradually varying index of refraction may be realized through a stepped configuration, and the distribution of the gradually increasing or decreasing index of refraction may include one of linear, polynomial, Gaussian and nonlinear distributions.

### Advantageous Effects

As described above, in a silicon multilayer anti-reflection film, a solar cell including the same and the manufacturing methods thereof according to the present invention, the index of refraction is adjusted by obliquely depositing silicon on a substrate through evaporation or sputtering such that the index of refraction of each silicon layer is gradually increased or decreased, thereby minimizing reflection of light between a semiconductor surface and air.

Also, according to the present invention, the silicon multilayer anti-reflection film may be formed of a single material, thereby enabling reduction of chamber contamination, variation of the index of refraction in a wide range, and manufacture through several simple deposition stages. Particularly, the silicon multilayer anti-reflection film according to the present invention is made of a semiconductor material such as silicon, which has a higher heat transfer coefficient than existing multilayered anti-reflection structures using oxide or fluoride, thereby enabling excellent heat dissipation.

Further, when the silicon multilayer anti-reflection film according to the present invention is applied to an existing silicon solar cell, there are advantages in that the anti-reflection film can also be made of the same material as the solar cell, and that the solar cell may have improved efficiency due to excellent heat dissipation of silicon having a high heat transfer coefficient without suffering from interior deterioration.

### DESCRIPTION OF DRAWINGS

FIG. 1 shows a sectional view of a silicon multilayer anti-reflection film and a graph depicting distribution of the index of refraction thereof, according to one embodiment of the present invention.

FIG. 2 is a diagram of a system for inclined deposition according to one embodiment of the present invention.

FIG. 3 shows SEM images of side-sections of a silicon substrate, on which a low refractive index silicon layer is deposited at various inclined angles, according to one embodiment of the present invention.

FIG. 4 shows graphs of the index of refraction and reflectivity of a low refractive index silicon layer deposited at various inclined angles according to one embodiment of the present invention.

FIGS. 5 to 7 show SEM images of silicon multilayer anti-reflection films, each of which include a structure having a gradually varying index of refraction on a silicon substrate, according to embodiments of the present invention.

FIG. 8 shows a graph depicting reflectivity of each of the silicon multilayer anti-reflection films, which include the structure having the gradually varying index of refraction on the silicon substrate, according to the embodiments of the present invention.

FIGS. 9 and 10 show average reflectivity depending on the thickness and the number of silicon multilayer anti-reflection films, each including a structure having a gradually varying index of refraction on the silicon substrate, according to one embodiment of the present invention.

FIG. 11 is a schematic view of a silicon solar cell in which a silicon multilayer anti-reflection film manufactured according to one embodiment of the present invention is placed.

### BEST MODE

Exemplary embodiments of the present invention will now be described in detail with reference to the accompanying drawings. However, it should be noted that the present invention may be embodied in various different forms without being limited to the illustrated embodiments. The following embodiments are set forth to provide a complete understanding of the present invention to a person having ordinary knowledge in the art.

First, in a method of manufacturing a silicon multilayer anti-reflection film have a gradually varying index of refraction according to one embodiment of the present invention, silicon is obliquely deposited on a substrate and inclination thereof is adjusted such that the index of refraction is gradually varied.

Also, a solar cell according to one embodiment of the present invention includes a p-type electrode, a p-i-n type semiconductor layer, an optical thin layer (that is, a silicon multilayer anti-reflection film), and a glass substrate, in which the optical thin layer has a multilayered structure in which the distribution of the index of refraction is gradually decreased.

The optical thin layer may have an index of refraction selected within the range from 1 to 5. The optical thin layer may be formed of a single material selected from the group consisting of crystalline, amorphous and intermediate-phase silicon. Here, the optical thin layer may have a porous structure.

Hereinafter, exemplary embodiments of a silicon multilayer anti-reflection film having a gradually varying index of refraction according to the present invention, and a solar cell including the same will be described in detail with reference to the accompanying drawings. However, it should be understood that the present invention is not limited to the following embodiments.

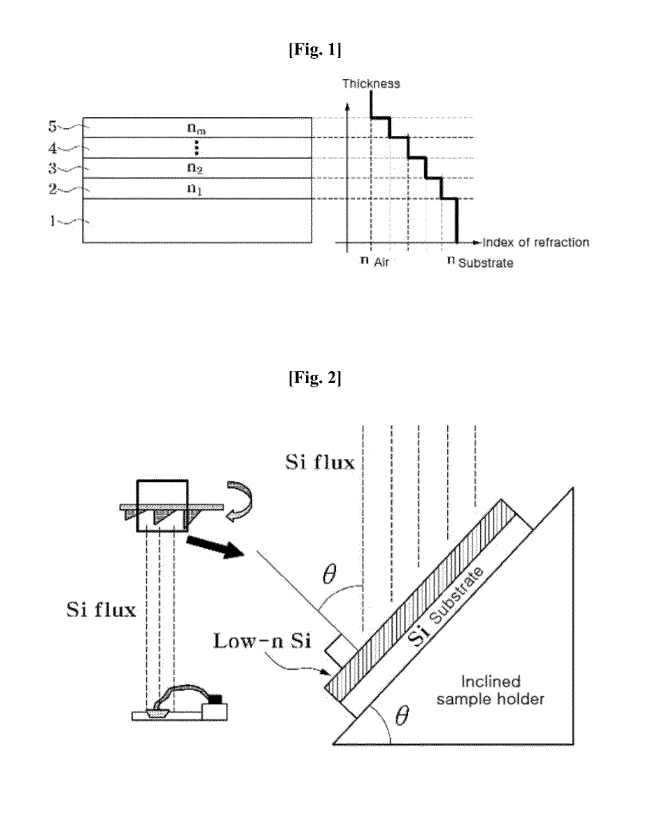

FIG. 1 shows a sectional view of a silicon multilayer anti-reflection film and a graph depicting distribution of the index of refraction thereof, according to one embodiment of the present invention.

Referring to FIG. 1, the silicon multilayer anti-reflection film according to the embodiment has a structure wherein an index of refraction is gradually varied from a high refractive index silicon layer 2 to a low refractive index silicon layer on a substrate 1.

Here, the substrate 1 may include a glass substrate or a semiconductor substrate, and the semiconductor substrate may be comprised of a material selected from, for example, Si, GaAs, InP, GaP, and GaN.

In the low refractive index silicon layer 5, the subscript ‘m’ indicates a positive integer. The distribution of the index of refraction of the anti-reflection film may have a stepped configuration. The subscript ‘m’ may be determined according to the structure, the substrate material, and the like. Here, each silicon layer may be formed through an inclined deposition process. For example, the silicon layers may be formed by sputtering or evaporation.

FIG. 2 is a diagram of a system for inclined deposition according to one embodiment of the present invention, in which the inclined deposition is performed by sputtering and evaporation. This diagram shows a basic system for achieving the present invention.

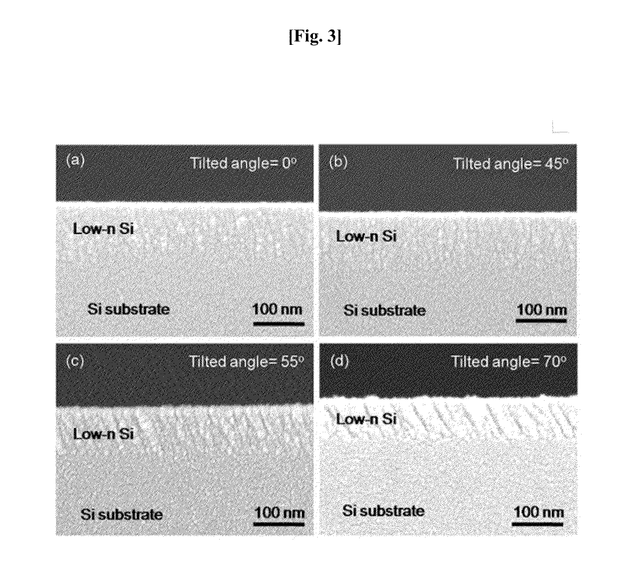

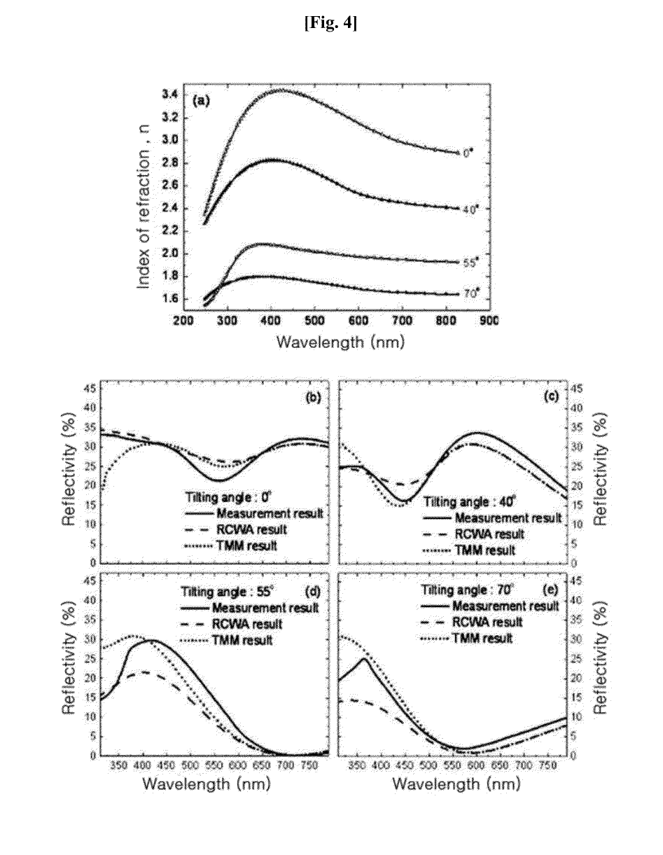

FIG. 3 shows SEM images of side-sections of a silicon substrate, on which a low refractive index silicon layer is deposited at various inclined angles, according to one embodiment of the present invention. These images are side-section images of a silicon thin film deposited by the process of FIG. 2.

Referring to FIG. 3, the tilting angle increases from (a) to (d), and thus nano-columns of the low refractive index silicon layer becomes deeper.

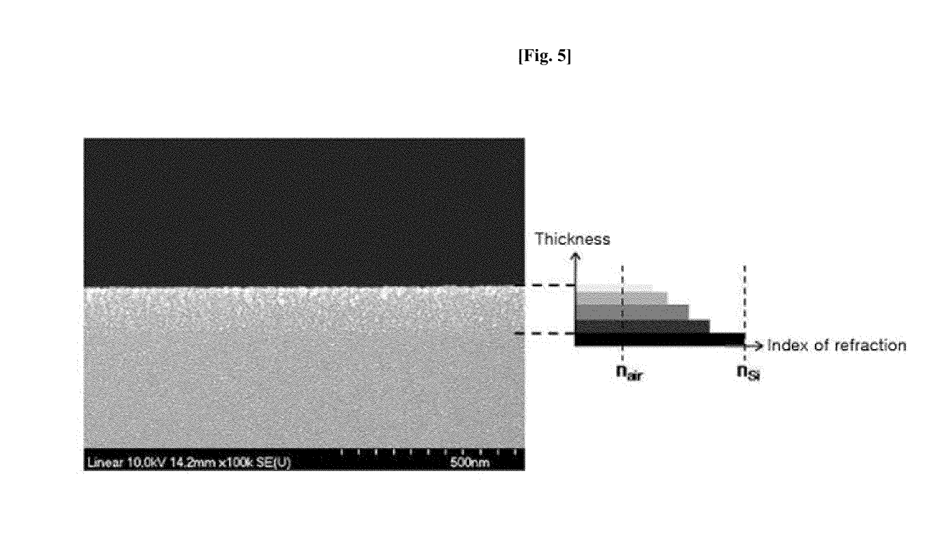

FIG. 4 shows graphs of the index of refraction and reflectivity of a low refractive index silicon layer deposited at various inclined angles according to one embodiment of the present invention.

Referring to FIG. 4, (a) is a graph depicting the index of refraction of one example of the low refractive index silicon layer depending on the tilting angle in a wavelength band from about 250 nm to about 820 nm. In FIG. 4(a), the index of refraction decreases with increasing inclined angle. At a tilting angle of about 70 degrees, the low refractive index silicon layer on the silicon substrate has an index of refraction of about 1.67 at a wavelength of about 633 nm.

FIGS. 4 (b), (c), (d) and (e) show the reflectivity of the low refractive index silicon layer. The reflectivity of the low refractive index silicon layer was calculated by Rigorous Coupled Wave Analysis (RCWA) and a Transmission Matrix Method (TMM) based on the indexes of refraction corresponding to the tilting angles as measured in the example.

In this embodiment, the silicon layer may be formed at a tilting angle ranging from about 0 degrees to 90 degrees (preferably, 1 to 90 degrees).

FIGS. 5 to 7 show SEM images of silicon multilayer anti-reflection films, each of which include a structure having a gradually varying index of refraction on a silicon substrate, according to embodiments of the present invention, in which silicon layers having various indexes of refraction are stacked.

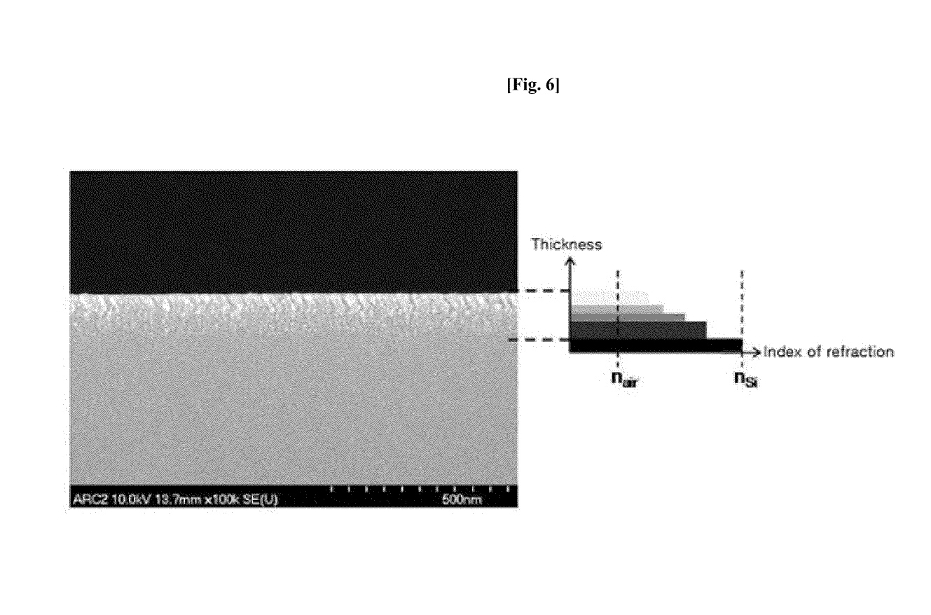

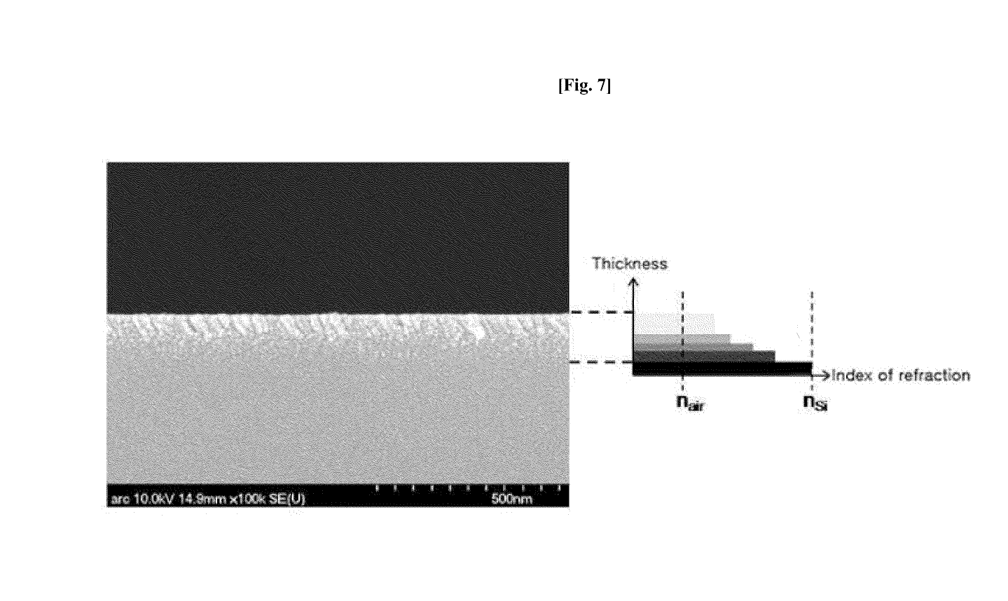

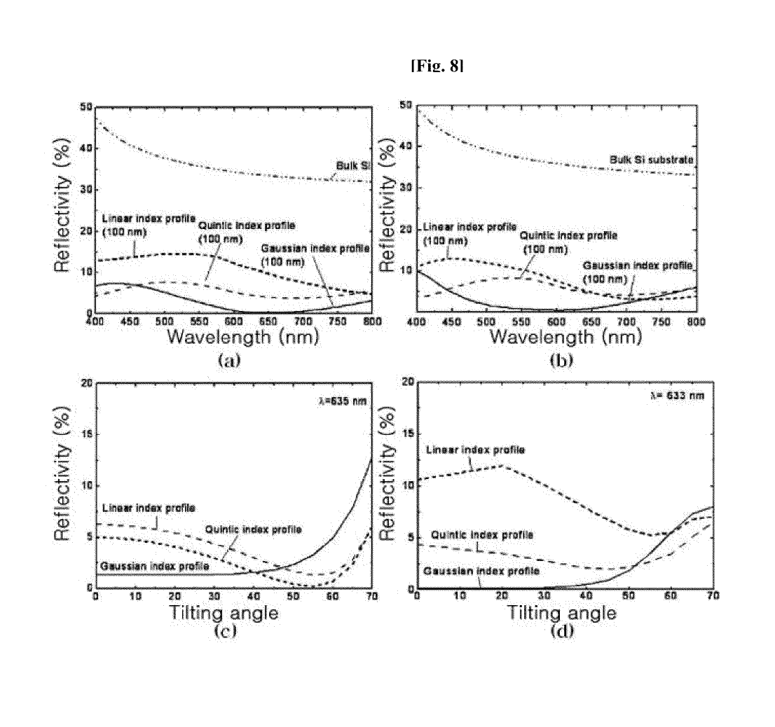

Referring to FIGS. 5 to 7, three examples of silicon layers are deposited on the silicon substrate and have a linear index distribution (FIG. 5), a quintic index distribution (FIG. 6) and a Gaussian index distribution (FIG. 7), respectively, and the distribution of the index of refraction of each silicon layer is represented in the form of a bar graph at a right side of each side-sectional image. In these examples, the silicon layers are formed to a total thickness of about 100 nm, and the thickness of each silicon layer is controlled to adjust the distribution of the index of refraction.

FIG. 8 shows a graph depicting reflectivity of each of the silicon multilayer anti-reflection films, which include the structure having the gradually varying index of refraction on the silicon substrate, according to the embodiments of the present invention.

FIGS. 8 (a) and (b) show the calculated reflectivity and the measured reflectivity of each example of the anti-reflection film, and the reflectivity of the silicon substrate thereof. It can be seen that anti-reflection properties of the anti-reflection film were varied within a wavelength range from about 400 nm to 800 nm depending on the distribution of the index of refraction thereof. Also, it can be seen that the theoretical calculation results (see FIG. 8(a)) and the measured results (FIG. 8(b)) are similar to each other.

FIGS. 8 (c) and (d) show the calculated reflectivity and the measured reflectivity of each example of the anti-reflection film according to the tilting angle. Here, the anti-reflection film has a reflectivity of about 10% or less even though an incident angle of light is tilted up to about 70 degrees.

As such, when silicon is obliquely deposited to form the anti-reflection film, there are many advantages in that the anti-reflection film may have anti-reflection properties within wide ranges of wavelengths and incident angles; the anti-reflection film may be formed by deposition of a single material, thereby preventing chamber contamination; the anti-reflection film has a wide range of the index of refraction and may suppress reflectivity despite a relatively small thickness; and the manufacturing process is more advantageous than that for the existing anti-reflection film, since fewer layers are used to form the anti-reflection film

Also, silicon is a semiconductor material and has a higher heat transfer coefficient than oxides and fluorides generally used in the art. Therefore, excellent temperature characteristics can be expected when silicon is, for example, applied to an optical device such as a solar cell or a light emitting diode.

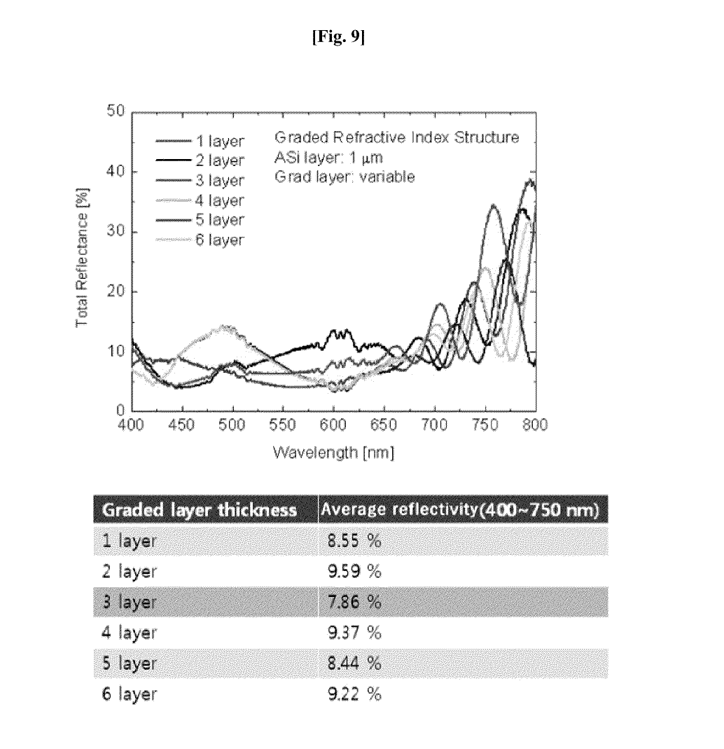

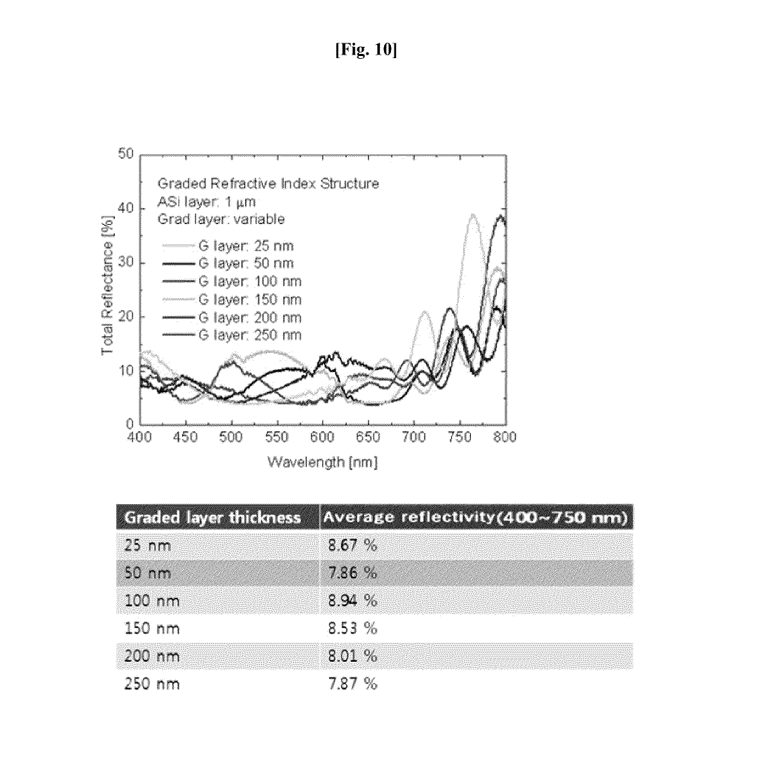

FIGS. 9 and 10 show average reflectivity depending on the thickness and the number of silicon multilayer anti-reflection films, each including a structure having a gradually varying index of refraction on the silicon substrate, according to one embodiment of the present invention, in which the lowest average reflectivity is about 7.86 when the silicon multilayer anti-reflection film has a thickness of 50 nm and includes three layers.

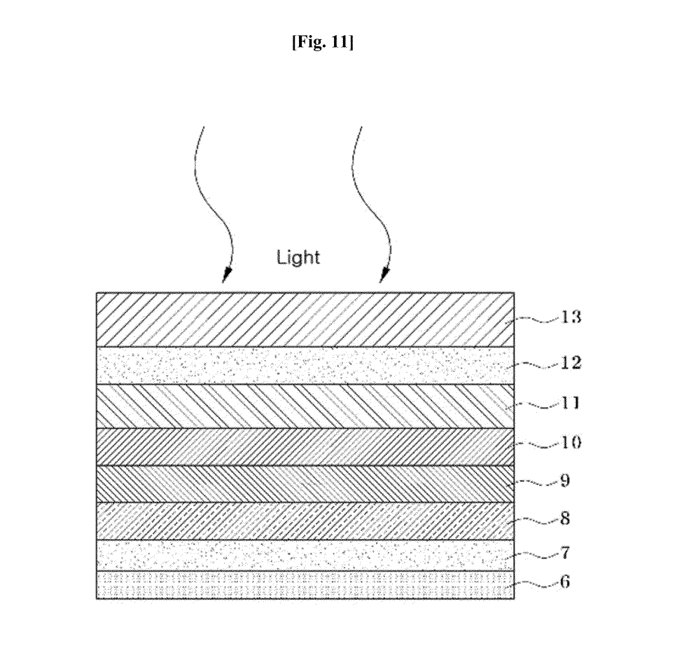

FIG. 11 is a schematic view of a silicon solar cell in which a silicon multilayer anti-reflection film manufactured according to one embodiment of the present invention is placed.

Referring to FIG. 11, the silicon solar cell, into which the silicon multilayer anti-reflection film according to the embodiment is inserted, includes a first transparent electrode layer 12, a p-type silicon layer 10, an i-type silicon layer 9, an n-type silicon layer 8, a second transparent layer 7, and a metal layer (or an n-type electrode) 6, which are sequentially stacked on the glass substrate 13.

In particular, an silicon multilayer anti-reflection film 11 is interposed between the first transparent electrode layer 12 and the p-type silicon layer 10 so that difference in index of refraction between the first transparent electrode layer 12 and the p-type silicon layer 10 can be decreased when sunlight enters the glass substrate 13, thereby suppressing reflectivity.

Also, the anti-reflection layer is comprised of the same material as the silicon solar cell, so that reflectivity on the interface between different materials can be minimized, as compared with reflectivity on the interface between different materials in the art.

In addition, the silicon multilayer anti-reflection film 11 according to this embodiment may be configured to have a gradually increasing index of refraction, and the tilting angle, the number of layers and the thickness of each layer may be selected in various combinations.

Further, the silicon multilayer anti-reflection film 11 may include 1 to 5 layers (preferably, 2 to 5 layers).

Meanwhile, although the embodiment of the present invention provides the solar cell layer, which includes the p-type silicon layer 10, the i-type silicon layer 9 and the n-type silicon layer 8, the present invention is not limited thereto. For example, the solar cell layer may be comprised of one material selected from among amorphous Si, crystalline Si, micro-crystalline Si, multi-crystalline Si, CIGS, CIS, and CdTe.

Although some exemplary embodiments have been described herein, the present invention is not limited thereto and that that various modifications, variations, and alterations can be made without departing from the spirit and scope of the present invention defined by the following claims and equivalents thereof.

1. A silicon multilayer anti-reflection film comprising at least two silicon layers sequentially stacked on a substrate, wherein each silicon layer is obliquely deposited on the substrate by adjusting a tilting angle of the substrate to gradually vary an index of refraction.

2. The silicon multilayer anti-reflection film according to claim 1, wherein the substrate comprises a glass substrate or a semiconductor substrate, and the semiconductor substrate comprises one of Si, GaAs, InP, GaP, and GaN.

3. The silicon multilayer anti-reflection film according to claim 1, wherein the silicon layer has a gradually increasing or decreasing index of refraction.

4. The silicon multilayer anti-reflection film according to claim 1, wherein the tilting angle ranges from 1 to 90 degrees.

5. The silicon multilayer anti-reflection film according to claim 1, wherein the gradually varying index of refraction is realized through a stepped configuration, and the distribution of the gradually varying index of refraction comprises one of linear, polynomial, Gaussian and nonlinear distributions.

6. A method of manufacturing a silicon multilayer anti-reflection film, comprising: sequentially stacking at least two silicon layers on a substrate, wherein each of the silicon layers is obliquely deposited on the substrate by adjusting a tilting angle of the substrate to have a gradually varying index of refraction.

7. The method according to claim 6, wherein the silicon layer is obliquely deposited by sputtering or evaporation.

8. The method according to claim 7, wherein each of the silicon layers is obliquely deposited to have a distribution of a gradually increasing or decreasing index of refraction.

9. The method according to claim 7, wherein the tilting angle ranges from 1 to 90 degrees.

10. The method according to claim 7, wherein the gradually varying index of refraction is realized through a stepped configuration, and the distribution of the gradually varying index of refraction comprises one of linear, polynomial, Gaussian and nonlinear distributions.

11. A solar cell including a silicon multilayer anti-reflection film, comprising:
a first transparent electrode formed on a substrate;
a silicon multilayer anti-reflection film obliquely formed on the first transparent electrode to have a gradually varying index of refraction;
a solar cell layer stacked on the silicon multilayer anti-reflection film;
a second transparent electrode formed on the solar cell layer; and
an n-type electrode formed on the second transparent electrode.

12. The solar cell according to claim 11, wherein the solar cell layer comprises at least one of amorphous Si, crystalline Si, micro-crystalline Si, multi-crystalline Si, CIGS, CIS, and CdTe.

13. The solar cell according to claim 11, wherein the substrate comprises a glass substrate or a semiconductor substrate, and the semiconductor substrate comprises one of Si, GaAs, InP, GaP, and GaN.

14. The solar cell according to claim 11, wherein the multilayered structure comprises two to five layers.

15. The solar cell according to claim 11, wherein the silicon multilayer anti-reflection film has a distribution of a gradually increasing or decreasing index of refraction.

16. The solar cell according to claim 11, wherein the gradually varying index of refraction is realized through a stepped configuration, and the distribution of the gradually varying index of refraction comprises one of linear, polynomial, Gaussian and nonlinear distributions.

17. A method of manufacturing a solar cell, comprising:
forming a first transparent electrode on a substrate;
obliquely forming a silicon multilayer anti-reflection film on the first transparent electrode to have a gradually varying index of refraction;
stacking a solar cell layer on the silicon multilayer anti-reflection film;
forming a second transparent electrode on the solar cell layer; and
forming an n-type electrode on the second transparent electrode.

18. The method according to claim 17, wherein the solar cell layer comprises at least one of amorphous Si, crystalline Si, micro-crystalline Si, multi-crystalline Si, CIGS, CIS, and CdTe.

19. The method according to claim 17, wherein the silicon multilayer anti-reflection film is formed to have a distribution of a gradually increasing or decreasing index of refraction.

20. The method according to claim 17, wherein the gradually varying index of refraction is realized through a stepped configuration, and the distribution of the gradually varying index of refraction comprises one of linear, polynomial, Gaussian and nonlinear distributions.
